(19) United States
(12) Patent Application Publication
(10) Pub. No.: US 2026/0348000 A1
(43) Pub. Date: Nov. 5, 2026

(54) COATING SYSTEM AND METHOD OF FORMING THE SAME

(71) Applicants: GE Avio S.r.l., Rivalta di Torino (IT); General Electric Company, Evendale, OH (US)

(72) Inventors: Francesco Vito, Napoli (IT); Marco Russo, Napoli (IT); Bangalore Aswatha Nagaraj, West Chester, OH (US)

(21) Appl. No.: 19/198,308

(22) Filed: May 5, 2025

(51) Int. Cl. C23C 14/58; C23C 14/14

(52) U.S. Cl. CPC C23C 14/5806; C23C 14/14

(57) ABSTRACT

A method of forming a coating system on a component including exposing a first portion of a surface of the component to a chromium-containing vapor via physical vapor deposition (PVD) at a temperature and a pressure to form a chromium-containing layer, and heating the chromium-containing layer on the first portion of the surface of the component at a treatment temperature in a protective atmosphere to form a diffusion layer on the first portion of the surface of the component and an outer layer on the diffusion layer. Following the heat treatment, the coated component includes a diffusion layer on the first portion of the surface of the component and an outer layer on the diffusion layer.

### FIELD

The present disclosure relates to a method of forming a coating system on the surface of a turbine engine component.

### BACKGROUND

Hot section components of gas turbine engines are often protected by a barrier coating, which prolongs the service life of the component by reducing the temperature of the underlying component. Ceramic materials, such as yttrium-stabilized zirconia (YSZ), are widely used as barrier coating materials because of their high temperature capability and low thermal conductivity.

Alternatively, chromide has been found to provide increased hot corrosion resistance and sufficient oxidation resistance at the lower temperatures. The current state of the art involves coating turbine engine components with chromide in selected locations using pack chromide and chemical vapor deposition (CVD).

### BRIEF DESCRIPTION OF THE DRAWINGS

A full and enabling disclosure of the present invention, including the best mode thereof, directed to one of ordinary skill in the art, is set forth in the specification, which makes reference to the appended figures, in which:

FIG. 1 is a cross-sectional view of a gas turbine engine;

FIG. 2 is a schematic view of a gas turbine blade;

FIG. 3A is a schematic view of a component having a chromium-containing layer on a first portion of the surface of the component in accordance with an exemplary embodiment;

FIG. 3B is a schematic view of a coating system in accordance with an exemplary embodiment;

FIG. 4A is a schematic view of a component having an existing thermal barrier coating on the surface of the component;

FIG. 4B is a schematic view of a component having an existing thermal barrier coating on the surface of the component after a second portion of the surface of the component has been masked in accordance with an exemplary embodiment;

FIG. 4C is a schematic view of a component having a chromium-containing layer on the surface of the component in accordance with an exemplary embodiment;

FIG. 4D is a schematic view of a coating system in accordance with an exemplary embodiment; and

FIG. 5 is a block flow diagram of an exemplary method of forming a coating system on a component.

### DEFINITIONS

The word “exemplary” is used herein to mean “serving as an example, instance, or illustration.” Any implementation described herein as “exemplary” is not necessarily to be construed as preferred or advantageous over other implementations. Additionally, unless specifically identified otherwise, all embodiments described herein should be considered exemplary.

The singular forms “a”, “an”, and “the” include plural references unless the context clearly dictates otherwise.

The term “at least one of” in the context of, e.g., “at least one of A, B, or C” refers to only A, only B, only C, or any combination of A, B, and C.

As used herein, the terms “first”, “second”, and “third” may be used interchangeably to distinguish one component from another and are not intended to signify location or importance of the individual components.

In the present disclosure, when a layer is being described as “on” or “over” another layer or component, it is to be understood that the layers can either be directly contacting each other or have another layer or feature between the layers. Thus, these terms are simply describing the relative position of the layers to each other and do not necessary mean “on top of” since the relative position above or below depends upon the orientation of the device to the viewer.

The term “gas turbine engine” refers to an engine having a turbomachine as all or a portion of its power source. Example gas turbine engines include turbofan engines, turboprop engines, turbojet engines, turboshaft engines, etc., as well as hybrid-electric versions of one or more of these engines.

As used herein, “superalloy” refers to an alloy having improved properties with respect to conventional alloys. For example, superalloys may have excellent physical characteristics, such as but not limited to: high mechanical strength, high thermal creep deformation resistance, high surface stability, and improved resistance to corrosion or oxidation. Exemplary superalloys can include nickel-base alloys, cobalt-base alloys, or iron-base alloys. Illustrative nickel-base superalloys are designated by the trade names Inconel®, Nimonic®, Rene®(such as, Rene® 80-, Rene® 95 alloys), and Udimet®. Exemplary superalloy material includes Rene 108, CM247, Haynes alloys, Incalloy, MP98T, TMS alloys, CMSX single crystal alloys. In embodiments, superalloys include those having a high gamma prime (γ′) value. “Gamma prime” (γ′) is the primary strengthening phase in nickel-based alloys. Example high gamma prime superalloys include but are not limited to: Rene 108, N5, GTD 444, MarM 247 and IN 738.

As used herein, the term “barrier coating(s)” can refer to environmental barrier coatings or thermal barrier coatings. The barrier coatings herein may be suitable for application to “components” found in high temperature environments (e.g., operating temperatures of about 2500 °C), such as those present in gas turbine engines. Examples of such components can include, for example, combustor components, turbine blades, shrouds, nozzles, heat shields, and vanes.

As used herein, the term “barrier material” refers to compositions that are useful for forming a layer of a barrier coating on a component, such as a layer of a thermal barrier coating (“TBC”). Barrier materials that are particularly suitable for forming a layer of an EBC may be referred to as “TBC material.”

As used herein, thermal barrier coating or “TBC” refers to a coating system comprising one or more layers capable of reducing heat flow to the underlying substrate of the article, that is, to form a thermal barrier. As used herein, the term “coating” refers to a material disposed on at least a portion of an underlying surface in a continuous or discontinuous manner. Further, the term “surface” does not necessarily mean an even surface, and the term “coating” does not necessarily mean a uniform thickness of the disposed material, and the disposed material may have a uniform or a variable thickness. The term “coating” may refer to a single layer of the coating material or may refer to a plurality of layers of the coating material. The coating material may be the same or different in the plurality of layers.

The TBC may generally include a ceramic thermal barrier material in one or more embodiments. For example, suitable ceramic thermal barrier coating materials may include various types of oxides, such as aluminum oxide (“alumina”), hafnium oxide (“hafnia”), or zirconium oxide (“zirconia”), in particular stabilized hafnia or stabilized zirconia, and blends including one or both of these. Examples of stabilized zirconia include without limitation yttria-stabilized zirconia, ceria-stabilized zirconia, calcia-stabilized zirconia, scandia-stabilized zirconia, magnesia-stabilized zirconia, india-stabilized zirconia, ytterbia-stabilized zirconia, lanthana-stabilized zirconia, gadolinia-stabilized zirconia, as well as mixtures of such stabilized zirconia. Similar stabilized hafnia compositions are known in the art and suitable for use in embodiments described herein.

In certain embodiments, the thermal barrier coating may include yttria-stabilized zirconia. Suitable yttria-stabilized zirconia may include from 1 weight percent to 20 weight percent yttria (based on the combined weight of yttria and zirconia), and more typically from 3 weight percent to 10 weight percent yttria. An example of yttria-stabilized zirconia thermal barrier coating includes 7% yttria and 93% zirconia. These types of zirconia may further include one or more of a second metal (e.g., a lanthanide, actinide, or the like) oxide, such as dysprosia, erbia, europia, gadolinia, neodymian, praseodymia, urania, and hafnia, to further reduce thermal conductivity of the thermal barrier coating material. In one or more embodiments, the thermal barrier coating material may further include an additional metal oxide, such as titania and/or alumina. For example, the thermal barrier coating may be composed of 8YSZ, though higher yttria concentrations may be utilized.

Suitable ceramic TBC materials may also include pyrochlores of general formula A₂B₂O₇ where A is a metal having a valence of 3+ or 2+ (e.g., gadolinium, aluminum, cerium, lanthanum, or yttrium) and B is a metal having a valence of 4+ or 5+ (e.g., hafnium, titanium, cerium, or zirconium) where the sum of the A and B valences is 7. Representative materials of this type include gadolinium zirconate, lanthanum titanate, lanthanum zirconate, yttrium zirconate, lanthanum hafnate, cerium hafnate, and lanthanum cerate.

Chemical elements are discussed in the present disclosure using their common chemical abbreviation, such as commonly found on a periodic table of elements. For example, hydrogen is represented by its common chemical abbreviation H; helium is represented by its common chemical abbreviation He; and so forth.

As used herein, the term “interface” generally means in contact with and adhered to. “Interfacing” may be between the deposited particles and/or between the deposited particles and the substrate/base particles.

As used herein, the term “substantially free” is understood to mean completely free of said constituent, or inclusive of trace amounts of same. “Trace amounts” are those quantitative levels of chemical constituent that are barely detectable and provide no benefit to the functional or aesthetic properties of the subject composition. The term “substantially free” also encompasses completely free.

As used herein, the term “substantially pure” is understood to mean the pure elemental substance.

As used herein, the term “PVD” refers to physical vapor deposition where the vapor is generated by an arc process.

### DETAILED DESCRIPTION

Reference will now be made in detail to present embodiments of the disclosure, one or more examples of which are illustrated in the accompanying drawings. The detailed description uses numerical and letter designations to refer to features in the drawings. Like or similar designations in the drawings and description have been used to refer to like or similar parts of the disclosure.

When forming a barrier coating containing chromide on a surface of a component, a halide activator may be used to transfer chromium via a halide vapor. However, the use of the halide activator causes a non-homogenous barrier coating to be formed due to the presence of halide inclusions throughout the composition. These halide inclusions result in a barrier coating weakened microstructure. Additionally, the presence of these halide inclusions have been found to degrade the barrier coatings by causing hot corrosion to occur when the coated component is exposed to high temperatures. Specifically, the halide ions react with the oxide components of the barrier coating which causes the formation of new chemical species that may further weaken the barrier coatings microstructure.

Additionally, the processes used to deposit chromide utilize a halide activator which is not conducive to repairing damaged barrier coatings, as the treatment temperatures are too high to allow for proper masking of surfaces where the coating is not desirable. For example, the use of a halide activator necessitates the use of masking materials that can withstand coating temperatures from 900 °C to 1100 °C. Accordingly, it would be desirable to have a controllable method of coating a component without the use of a halide activator in order to increase the barrier coating's ability to resist environmental damage and therefore prolong the service life of the underlying component.

A method of coating a component without the use of a halide activator via physical vapor deposition (PVD) is presently disclosed. The method also includes heat treating the coated component to form a diffusion layer and an outer layer, which results in a coating system having increased performance due to the improved microstructure as compared to the current state of the art. Thus, improved coated components may result for use in gas turbine engines.

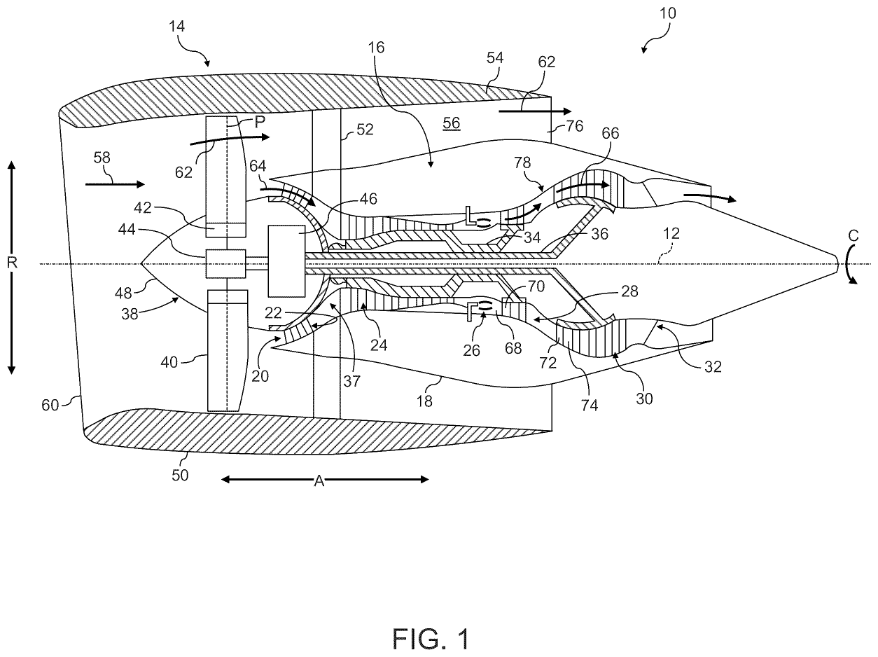

For example, referring now to the drawings, wherein identical numerals indicate the same elements throughout the figures, FIG. 1 is a schematic cross-sectional view of a gas turbine engine in accordance with an exemplary embodiment of the present disclosure. More particularly, for the embodiment of FIG. 1, the gas turbine engine is a high-bypass turbofan jet engine, sometimes also referred to as a “turbofan engine.” As shown in FIG. 1, the gas turbine engine 10 defines an axial direction A (extending parallel to a longitudinal centerline 12 provided for reference), a radial direction R, and a circumferential direction C extending about the longitudinal centerline 12. In general, the gas turbine engine 10 includes a fan section 14 and a turbomachine 16 disposed downstream from the fan section 14.

The exemplary turbomachine 16 depicted generally includes a substantially tubular outer casing 18 that defines an annular inlet 20. The outer casing 18 encases, in serial flow relationship, a compressor section including a booster or low pressure (LP) compressor 22 and a high pressure (HP) compressor 24; a combustion section 26; a turbine section including a high pressure (HP) turbine 28 and a low pressure (LP) turbine 30; and a jet exhaust nozzle section 32. A high pressure (HP) shaft 34 (which may additionally or alternatively be a spool) drivingly connects the HP turbine 28 to the HP compressor 24. A low pressure (LP) shaft 36 (which may additionally or alternatively be a spool) drivingly connects the LP turbine 30 to the LP compressor 22. The compressor section, combustion section 26, turbine section, and jet exhaust nozzle section 32 together define a working gas flowpath 37.

For the embodiment depicted, the fan section 14 includes a fan 38 having a plurality of fan blades 40 coupled to a disk 42 in a spaced apart manner. As depicted, the fan blades 40 extend outwardly from disk 42 generally along the radial direction R. Each fan blade 40 is rotatable relative to the disk 42 about a pitch axis P by virtue of the fan blades 40 being operatively coupled to a suitable pitch change mechanism 44 configured to collectively vary the pitch of the fan blades 40, e.g., in unison. The gas turbine engine 10 further includes a power gear box 46, and the fan blades 40, disk 42, and pitch change mechanism 44 are together rotatable about the longitudinal centerline 12 by LP shaft 36 across the power gear box 46. The power gear box 46 includes a plurality of gears for adjusting a rotational speed of the fan 38 relative to a rotational speed of the LP shaft 36, such that the fan 38 may rotate at a more efficient fan speed.

Referring still to the exemplary embodiment of FIG. 1, the disk 42 is covered by rotatable front hub 48 of the fan section 14 (sometimes also referred to as a “spinner”). The front hub 48 aerodynamically contoured to promote an airflow through the plurality of fan blades 40.

Additionally, the exemplary fan section 14 includes an annular fan casing or outer nacelle 50 that circumferentially surrounds the fan 38 and/or at least a portion of the turbomachine 16. It should be appreciated that the nacelle 50 is supported relative to the turbomachine 16 by a plurality of circumferentially-spaced outlet guide vanes 52 in the embodiment depicted. Moreover, a downstream section 54 of the nacelle 50 extends over an outer portion of the turbomachine 16 so as to define a bypass airflow passage 56 therebetween.

During operation of the gas turbine engine 10, a volume of air 58 enters the gas turbine engine 10 through an associated inlet 60 of the nacelle 50 and fan section 14. As the volume of air 58 passes across the fan blades 40, a first portion of air 62 is directed or routed into the bypass airflow passage 56 and a second portion of air 64 as indicated by arrow 64 is directed or routed into the working gas flowpath 37, or more specifically into the LP compressor 22. The ratio between the first portion of air 62 and the second portion of air 64 is commonly known as a bypass ratio. A pressure of the second portion of air 64 is then increased as it is routed through the HP compressor 24 and into the combustion section 26, where it is mixed with fuel and burned to provide combustion gases 66.

The combustion gases 66 are routed through the HP turbine 28 where a portion of thermal and/or kinetic energy from the combustion gases 66 is extracted via sequential stages of HP turbine stator vanes (sometimes also referred to as a “nozzle”) 68 that are coupled to the outer casing 18 and HP turbine rotor blades 70 that are coupled to the HP shaft 34, thus causing the HP shaft 34 to rotate, thereby supporting operation of the HP compressor 24. The combustion gases 66 are then routed through the LP turbine 30 where a second portion of thermal and kinetic energy is extracted from the combustion gases 66 via sequential stages of LP turbine stator vanes 72 that are coupled to the outer casing 18 and LP turbine rotor blades 74 that are coupled to the LP shaft 36, thus causing the LP shaft 36 to rotate, thereby supporting operation of the LP compressor 22 and/or rotation of the fan 38.

The combustion gases 66 are subsequently routed through the jet exhaust nozzle section 32 of the turbomachine 16 to provide propulsive thrust. Simultaneously, the pressure of the first portion of air 62 is substantially increased as the first portion of air 62 is routed through the bypass airflow passage 56 before it is exhausted from a fan nozzle exhaust section 76 of the gas turbine engine 10, also providing propulsive thrust. The HP turbine 28, the LP turbine 30, and the jet exhaust nozzle section 32 at least partially define a hot gas path 78 for routing the combustion gases 66 through the turbomachine 16.

It should be appreciated, however, that the exemplary gas turbine engine 10 depicted in FIG. 1 is by way of example only, and that in other exemplary embodiments, the gas turbine engine 10 may have any other suitable configuration. For example, although the gas turbine engine 10 depicted is configured as a ducted gas turbine engine (i.e., including the outer nacelle 50), in other embodiments, the gas turbine engine 10 may be an unducted gas turbine engine (such that the fan 38 is an unducted fan, and the outlet guide vanes 52 are cantilevered from the outer casing 18). Additionally, or alternatively, although the gas turbine engine 10 depicted is configured as a geared gas turbine engine (i.e., including the power gear box 46) and a variable pitch gas turbine engine (i.e., including a fan 38 configured as a variable pitch fan), in other embodiments, the gas turbine engine 10 may additionally or alternatively be configured as a direct drive gas turbine engine (such that the LP shaft 36 rotates at the same speed as the fan 38), as a fixed pitch gas turbine engine (such that the fan 38 includes fan blades 40 that are not rotatable about a pitch axis P), or both. It should also be appreciated, that in still other exemplary embodiments, aspects of the present disclosure may be incorporated into any other suitable gas turbine engine. For example, in other exemplary embodiments, aspects of the present disclosure may (as appropriate) be incorporated into, e.g., a turboprop gas turbine engine, a turboshaft gas turbine engine, or a turbojet gas turbine engine.

Various components of the gas turbine engine can include the coating system of the present disclosure. For example, in various embodiments, the articles can include, without limitation, a turbine engine component selected from the group consisting of a turbine blade 40, a turbine blade underplatform 89, a turbine nozzle 68, a structural ring, a turbine disk 42, a turbine vane 72, a turbine blade shank root 91, or a turbine tubular casing 18.

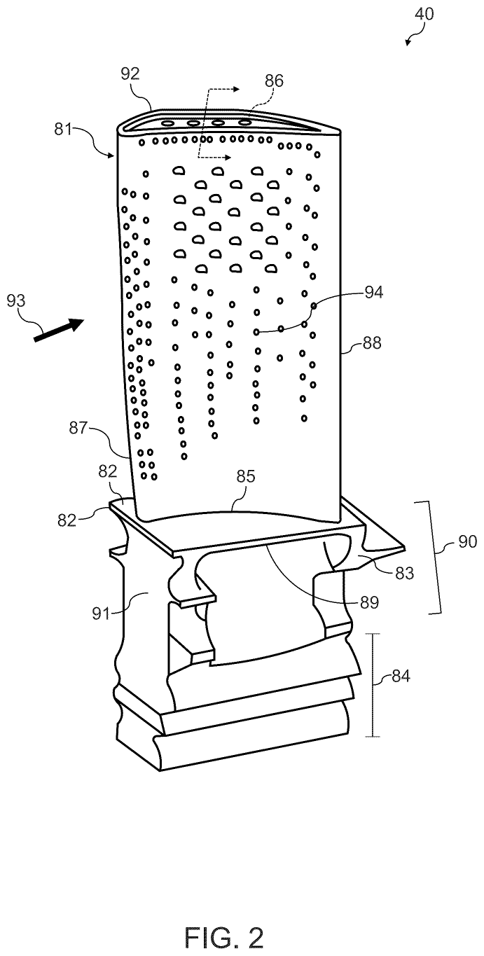

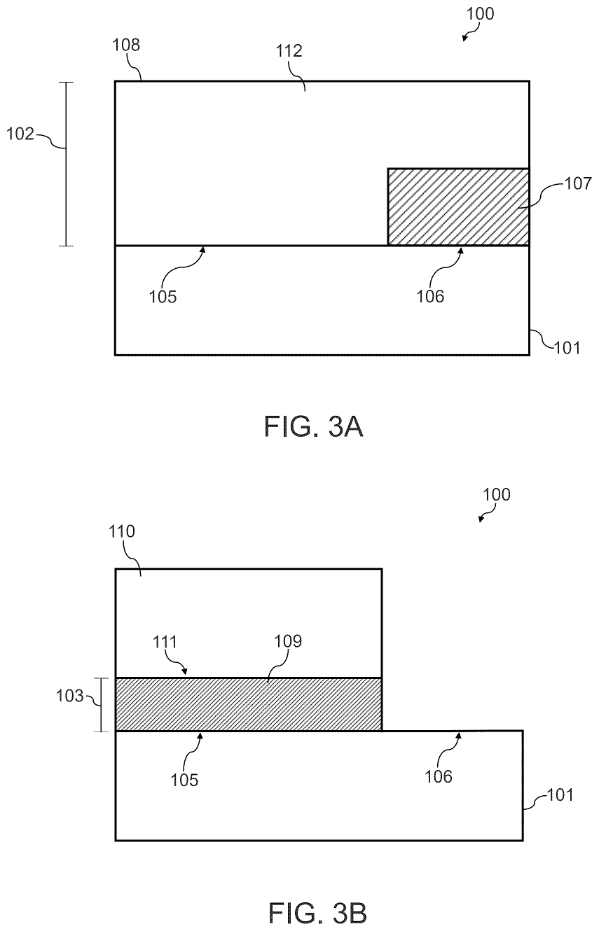

Referring now to FIG. 2, a schematic view of a gas turbine blade 40 is provided. The blade 40 includes an airfoil 81, a platform 82, a shank 83, and a supporting serrated region 84 having a dovetail configuration formed in a unitary configuration. The platform 82 defines a radially inner boundary for hot combustion gases 93 generated in an upstream combustion (not shown) which flow axially downstream over the airfoil 81 during operation. The turbine blade 40 is formed of any operable material, such as a superalloy (e.g. a nickel-based superalloy), which is the base metal of the turbine blade 40. In one embodiment, the base metal of the turbine blade 40 may also serve as a surface of a component, for example, shown in FIG. 3.

The airfoil 81 includes a generally concave pressure sidewall 85, and a circumferentially opposite, generally convex suction sidewall 86 extending in radial or longitudinal span from a radially inner root 91 where the proximal end of the airfoil 81 meets the platform 82, to a radially outer tip 92 at the opposite distal end of the airfoil 81. The two sidewalls also extend axially in chord between a leading edge 87 and an opposite trailing edge 88. The airfoil 81 is exposed to hot combustion gases 93 while in operation. Thus, to increase the temperature resistance and cooling properties of the airfoil 81, cooling holes 94 are dispersed throughout the body of the airfoil 81.

The shank 83 may be used to attach the blades 40 to the disk 42 or other component. The shank 83 may include several features such as the root 91. The root 91 may include a serrated region 84 and an underplatform region 90. The serrated region 84 on the shank 83 may be configured to attach the blade 40 to the disk 42. Specifically, the serrated region 84 may be configured with supporting lobes or tangs that mate with a corresponding serrated region 84 slot in the perimeter of a supporting rotor disk 42 from which the blade 40 extends radially outwardly in the engine. The shank 83 operates at lower temperatures than that of the airfoil 81.

The platform 82 generally defines a boundary that lies between the airfoil 81 and the shank 83. The proximal end of the airfoil 81 meets the platform 82, and the distal end of the shank 83 meets the platform 82. has a top surface and a bottom surface. Additionally, the platform 82 may have an underplatform 89 damper (UPD), which are commonly used in gas turbine engines to mitigate the risk of high-cycle fatigue failure of the blades 40.

Generally, the airfoil 81 is exposed to hot combustion gas 93, and the shank 83 is not exposed to hot combustion gas 93. This configuration may result in the shank 83 operating at temperatures lower than those at which the airfoil 81 operates

The airfoil 81 is exposed to hot combustion gases 93 while in operation, which may cause degradation of the underlying component. Thus, to prevent degradation and improve service life, the component may be coated in accordance with an exemplary embodiment.

For example, FIGS. 3A-3B show the formation of a coating system 100 on the surface of a component 101. Specifically, FIG. 3A illustrates an embodiment of the component 101 having a chromium-containing layer 112 on a first portion 105 of the surface of the component 101. In embodiments, the component 101 may be any material, such as a ceramic, or a metal alloy such as a superalloy. More particularly, in embodiments, the component 101 may include a metal alloy, such as a nickel or cobalt based superalloy (e.g., those available under the name Inconel® available from Special Metals Corporation). In embodiments, the component 101 may include composite materials such as metal matrix composites (MMCs). In embodiments, the component 101 may be a component of a gas turbine engine, such as described in FIG. 1. For example, in embodiments, the component 101 may be an airfoil, such as the airfoil 81 (FIG. 2).

In embodiments, the component 101 may comprise a surface which is defined by the first portion 105 of the surface of the component 101, and a second portion 106 of the surface of the component 101. In embodiments, the first portion 105 of the surface of the component 101 may be where the coating system 100 is desirable. In embodiments, the second portion 106 of the surface of the component 101 may be where the coating system 100 is not desirable. For example, the first portion 105 of the surface of the component 101 may comprise an underplatform region, such as underplatform region 90 (FIG. 2), of an airfoil, and the second portion 106 of the surface of the component 101 may comprise a serrated region, such as serrated region 84 (FIG. 2), of an airfoil.

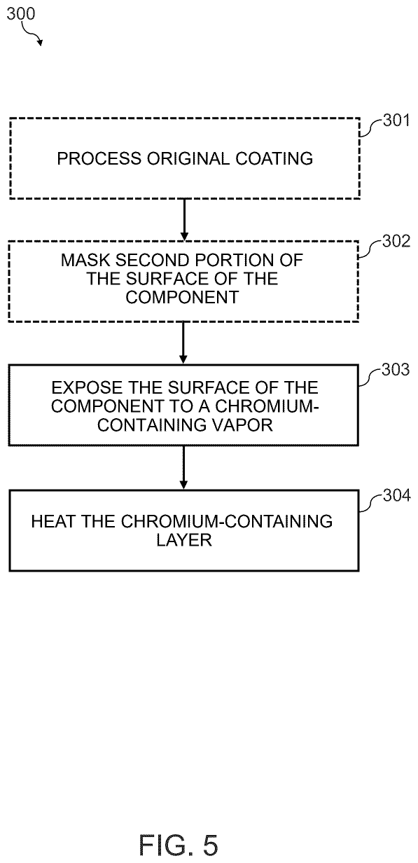

In embodiments, the first portion 105 of the surface of the component 101 may be exposed to a chromium-containing vapor 108 via physical vapor deposition (PVD) at a temperature and a pressure to form the chromium-containing layer 112 on the first portion of the surface of the component. As described below in FIG. 5, an energy source may be directed onto a source material to vaporize the source material, thus forming the chromium-containing vapor 108 which may condense on the surface of the component 101 to form the chromium-containing layer 112. In embodiments, the chromium-containing vapor 108 may be substantially free of a halide activator. In embodiments, the chromium-containing vapor 108 may comprise chromium. In embodiments, the chromium-containing vapor 108 may be at least 90 wt. % chromium. In embodiments, the chromium-containing vapor 108 may comprise from 95 wt. % to 100 wt. % chromium. In embodiments, the chromium-containing vapor 108 may comprise substantially pure chromium. In this exemplary embodiment, the chromium-containing vapor 108 may be substantially free of inclusions (i.e. Cl, F, Br, I, or other halides).

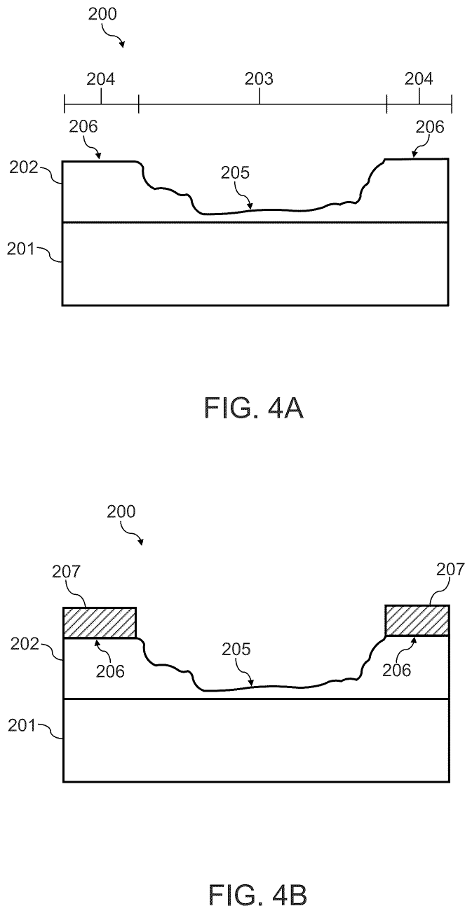

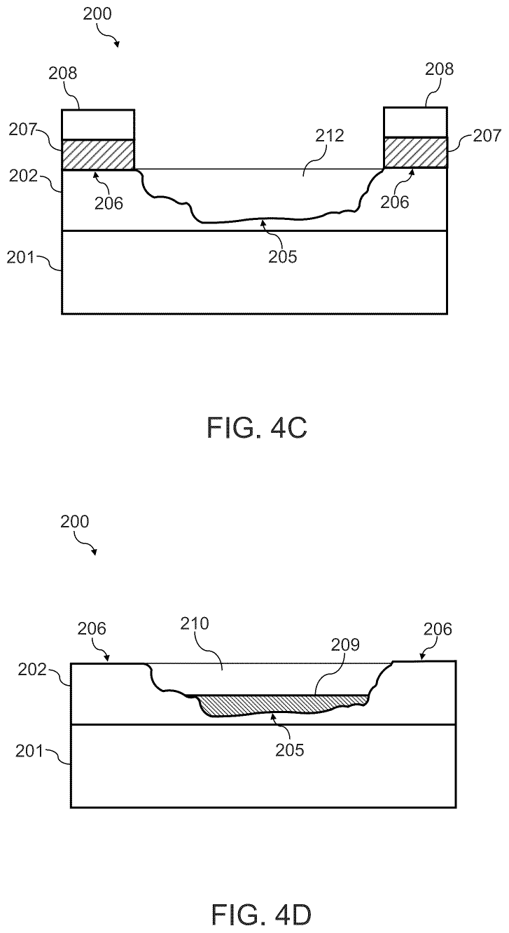

In embodiments, the chromium-containing vapor 108 may condense on the first portion 105 of the surface of the component 101 to form a thin, solid film or coating. In embodiments, the thin, solid film or coating may be the chromium-containing layer 112. In embodiments, the chromium-containing layer 112 may comprise chromium. In embodiments, the chromium-containing layer 112 may be at least 90 wt. % chromium. In embodiments, the chromium-containing layer 112 may comprise from 95 wt. % to 100 wt. % chromium. In embodiments, the chromium-containing layer 112 may comprise substantially pure chromium. In this exemplary embodiment, the chromium-containing layer 112 may be substantially free of inclusions (i.e. Cl, F, Br, I, or other halides). In embodiments, the chromium-containing 112 layer may have a thickness which is dependent upon the depth of damage to an existing TBC 202 (FIGS. 4A-4C). In embodiments, the chromium-containing layer 112 may have a thickness 102 of 1 μm to 30 μm.

In embodiments, it may not be desirable to form a chromium-containing layer 112 on the second portion 106 of the surface of the component 101. For example, in embodiments, it may not be desirable to form a chromium-containing layer 112 on a serrated region, such as serrated region 84 (FIG. 2), of an airfoil. In embodiments, the serrated region 84 of the gas turbine blade 40 may form or define the second portion 106 of the surface of the component 101 that may be masked in accordance with an exemplary embodiment. In embodiments, a mask 107 may be applied on the second portion 106 of the surface of the component 101 to avoid forming a chromium-containing layer 112 on the second portion 106 of the surface of the component 101. For example, in embodiments, the mask 107 may be exposed to the chromium-containing vapor 108, which may prevent the formation of a chromium-containing layer 112 on the second portion 106 of the surface of the component 101. In embodiments, if the second portion 106 of the surface of the component 101 has been masked, the mask 107 may be removed either before or after the coating system 101 (FIG. 3B) is formed.

In embodiments, the chromium-containing layer 112 may be heated to form the coating system 100. Referring now to FIG. 3B, the coating system 100 may comprise a diffusion layer 109 and an outer layer 110. The outer layer 110 may also be referred to as an “additive layer.” In embodiments, the outer layer 110 may be substantially free of voids and cracks. In embodiments, the outer layer 110 may have a porosity from 0% by volume to 5% by volume. In another embodiment, the outer layer 110 may be at least 90 weight % (wt %) chromium (e.g. 95 wt. % to 100 wt. % Cr). In one embodiment, the outer layer 110 may be free of other elemental inclusions. In one embodiment, the outer layer 110 may comprise substantially pure chromium.

In embodiments, the diffusion layer 109 may be present on the first portion 105 of the surface of the component 101 and the outer layer 110 may be present on a surface 111 defined by the diffusion layer 109. In embodiments, the outer layer 110 may interface with the diffusion layer 109 at the surface 111 defined by the diffusion layer 109, and the diffusion layer 109 may interface with the component 101 at the first portion 105 of the surface of the component 101. For example, in embodiments, the diffusion layer 109 may chemically bond and/or fuse the outer layer 110 to the first portion 105 of the surface of the component 101.

In embodiments, the diffusion layer 109 may have a diffusion thickness 103 from 1 μm to 10 μm. The diffusion thickness 103 may be dependent on the treatment temperature and the time of heating. More particularly, a ratio of the thickness of the outer layer 110 and the diffusion thickness 103 of the diffusion layer 109 may be dependent on the time of heating and treatment temperature.

In embodiments, as shown in FIGS. 4A-4D, a thermal barrier coating (TBC) 202 present on a component 201 may be repaired or upgraded according to an exemplary embodiment. If desired, the TBC 202 may be removed before coating the component 201 according to the method of one embodiment. In another embodiment, the TBC 202 may be left on the component 201 for repair or upgrade.

In embodiments, the component 201 may comprise a first portion 205 of a surface of the component 201, and a second portion 206 of the surface of the component 201. In embodiments, the first portion 205 of the surface of the component 201 may define where a coating system 200 is desirable. In embodiments, the second portion 206 of the surface of the component 201 may define where a coating system 200 is not desirable. For example, as shown in FIG. 4A, the existing TBC 202 present on the component 201 may comprise a damaged region 203 and an undamaged region 204. In embodiments, when the TBC 202 is left on the component 201, the damaged region 203 may form the first portion 205 of the surface of the component 201 and the undamaged region 204 may form the second portion 206 of the surface of the component 201.

As shown in FIG. 4B, the second portion 206 of the surface of the component 201 of FIG. 4A may be masked to avoid forming a chromium-containing layer 212 (FIG. 4C) on the second portion 206 of the surface of the component 201. In embodiments, it may not be desirable to form a chromium-containing layer 212 on an undamaged region, such as undamaged region 204 (FIG. 4A), of a TBC. For example, in embodiments, a mask 207 may be applied to the undamaged region 204 of the TBC. In embodiments, the mask 207 may be exposed to a chromium-containing vapor 208, which prevents the formation of a chromium-containing layer 212 on the second portion 206 of the surface of the component 201. In embodiments, the mask 207 may be removed prior to or after heating.

As depicted in FIG. 4C, the TBC 202 may be repaired by forming the chromium-containing layer 212 on the first portion 205 of the surface of the component 201 at a temperature and a pressure. In embodiments when a mask 207 has been applied to the second portion 206 of a surface of a component 201, the mask 207 may be exposed to the chromium-containing vapor 208 to form the chromium-containing layer 212 on the mask 207.

In embodiments, the chromium-containing vapor 208 may comprise chromium. In embodiments, the chromium-containing vapor 208 may be at least 90 wt. % chromium. In embodiments, the chromium-containing vapor 208 may comprise from 95 wt. % to 100 wt. % chromium. In embodiments, the chromium-containing vapor 208 may comprise substantially pure chromium. In this exemplary embodiment, the chromium-containing vapor 208 may be substantially free of inclusions (i.e. Cl, F, Br, I, or other halides).

After exposure, the chromium-containing vapor 208 may condense to form the chromium-containing layer 212 on the first portion 205 of the surface of the component 201. In embodiments, the chromium-containing layer may comprise chromium. In embodiments, the chromium-containing layer 212 may be at least 90 wt. % chromium. In embodiments, the chromium-containing layer 212 may comprise from 95 wt. % to 100 wt. % chromium. In embodiments, the chromium-containing layer 212 may comprise substantially pure chromium. In this exemplary embodiment, the chromium-containing layer 212 may be substantially free of inclusions (i.e. Cl, F, Br, I, or other halides). In embodiments, the chromium-containing layer 212 may have a thickness which is dependent upon the depth of damage to the existing TBC 202. In embodiments, the chromium-containing layer 212 may have a thickness of 1 μm to 30 μm.

In embodiments, the chromium-containing layer 212 may be heated in accordance with an embodiment, such as the embodiment described below in FIG. 5, to form a coating system on the first portion 205 of the surface of the component 201. As shown in FIG. 4D, a coating system may be formed on the first portion 205 of the surface of the component 201, such as described above in FIG. 3B. In embodiments when the second portion 206 of the surface of the component 201 is masked, the coating system may not be present on the second portion 206 of the surface of the component 201. In embodiments, the resulting coating system 200 may comprise an existing TBC 202 on the component 201, a diffusion layer 209 on the first portion 205 of the surface of the component 201 similar to the diffusion layer 109 as described above in FIG. 3B, and an outer layer 210 on the diffusion layer 209 similar to the outer layer 110 as described above in FIG. 3B.

Referring now to FIG. 5, a block flow diagram of an exemplary method 300 of forming a coating system 100, 200 on a component 101, 201 is provided. The method 300 of FIG. 5 may be utilized to coat the component 101, 201 to form the coating system 100, 200 as described above in FIGS. 3A-3B and 4A-4D.

Accordingly, it will be appreciated that the method 300 may generally be utilized to coat the component 101, 201 as described herein. However, in other exemplary aspects, the method 300 may additionally or alternatively be utilized to coat any other suitable component. In addition, although FIG. 5 depicts steps performed in a particular order for purposes of illustration and discussion, the methods discussed herein are not limited to any particular order or arrangement. One of skill in the art, using the disclosures provided herein, will appreciate that various steps of methods disclosed herein can be omitted, rearranged, combined, and/or adapted in various way without deviating from the scope of the present subject matter.

As depicted, the exemplary method 300 optionally includes at block 301 processing an original coating. In embodiments, the component 201 may have a TBC 202 present, forming a first portion 205 of the surface of the component 201 and second portion 206 of the surface of the component 201, such as described above in FIG. 4A. If desired, the existing TBC 202 may be removed before coating the component 201 according to the method 300 of one embodiment. In another embodiment, the existing TBC 202 may be left on the surface of the component 201 for repair or upgrade, as described above in FIG. 4A-4D.

As depicted at block 302, the method 300 optionally includes masking a second portion 106, 206 of the surface of the component 101, 201, such as described above in FIGS. 3A and 4B-4C.

In embodiments, the method 300 includes at block 303 exposing the first portion 105, 205 of the surface of the component 101, 201 to a chromium-containing vapor 108, 208. More particularly, the coating system 100, 200 may be formed by first exposing the first portion 105, 205 of the surface of the component 101 to the chromium-containing vapor 108, 208 via PVD at a temperature and a pressure to form a chromium-containing layer 112, 212, such as described above in FIGS. 3A and 4C. In embodiments, an energy source may be directed onto a source material to vaporize the source material, thus forming the chromium-containing vapor 108, 208. In embodiments, the chromium-containing vapor 108, 208 may condense on the surface of the component 101, 201 to form the chromium-containing layer 112, 212.

In one embodiment, the temperature may be 350 °C to 500 °C. In one embodiment, the pressure may be 0 atmosphere (atm) to 1 atm of inert gas.

As depicted at block 304, the component 101, 201 having the chromium-containing layer 112, 212 on the first portion 105, 205 of the surface of the component 101, 201 may be heat treated in a protective atmosphere. In embodiments, the protective atmosphere may be a vacuum. In embodiments, the heat treatment may be conducted at a treatment temperature from 600 °C to 1100 °C. In embodiments, the heat treatment may be conducted at a temperature from 700 °C to 900 °C. In embodiments, the heat treatment may be for a time from 3 hours to 12 hours.

In embodiments, the heat treatment may instigate the formation of a diffusion layer 109, 209 that chemically bonds the outer layer 110, 210 to the first portion 105, 205 of the surface of the component 101, 201. The diffusion layer 109, 209 may be formed between the first portion 105, 205 of the surface of the component 101, 201 and the outer layer 110, 210. The diffusion layer 109 may have a diffusion thickness 103 from 1 μm to 10 μm. The diffusion layer 109 may have a diffusion thickness 103 from 1 μm to 5 μm.

In embodiments, the method 300 may improve the metallurgical microstructure properties of the coating system 100, 200. For example, in embodiments, the method 300 may form an outer layer 110, 210 that is 95 wt. % of the desired composition. In one embodiment, the outer layer 110, 210 may comprise greater than 95 wt. % chromium (e.g. 95 wt. % to 100 wt. % Cr). In one embodiment, the outer layer 110, 210 may comprise substantially pure chromium. For example, one embodiment may produce an outer layer 110, 210 having less than 5% voids and is substantially free of inclusions from inclusions (i.e. Cl, F, Br, I, or other halides). Additionally, one embodiment may provide for the formation of a dense outer layer 110, 210 having a porosity from 0% by volume to 5% by volume.

When repairing an existing TBC 202, surfaces where a coating system is not desirable are relatively difficult to mask due to their location relative to the desired surfaces. Specifically, the PVD process may allow for the use of diverse masking materials since the temperature is decreased in comparison to the current art. The masking process may be simplified and the coating of a component may be repaired. Unlike the state of the art process using a halide activator, the method of forming a coating system on component as described herein is compatible with existing zirconia-based TBC at other locations of the component. Masking the TBC to prevent reactions with vapors of halides is challenging, and the PVD process enables a thermal barrier coated component to be chromium coated in other locations of the component. However, other advantages of the subject matter described herein also may be realized by those of ordinary skill in the art.

Further aspects are provided by the subject matter of the following clauses:

A method of forming a coating system on a component, the method comprising: exposing a first portion of a surface of the component to a chromium-containing vapor via physical vapor deposition (PVD) at a temperature and a pressure to form a chromium-containing layer on the first portion of the surface of the component; and heating the chromium-containing layer on the first portion of the surface of the component at a treatment temperature in a protective atmosphere to form a diffusion layer on the first portion of the surface of the component and an outer layer on the diffusion layer.

The method of any previous clause, wherein the chromium-containing vapor comprises at least 90 wt. % chromium.

The method of any previous clause, wherein the chromium-containing vapor is substantially free of a halide.

The method of any previous clause, wherein the chromium-containing layer has a thickness from 1 μm to 30 μm.

The method of any previous clause, wherein the outer layer is substantially free of inclusions.

The method of any previous clause, wherein the outer layer has a porosity from 0% by volume to 5% by volume.

The method of any previous clause, wherein the diffusion layer has a thickness from 1 μm to 10 μm.

The method of any previous clause, wherein the component is at least one of a turbine blade, a turbine nozzle, a structural ring, a turbine disk, or a turbine casing.

The method of any previous clause, further comprising: prior to exposing the first portion of the surface of the component to the chromium-containing vapor, masking a second portion of the surface of the component.

The method of any previous clause, wherein the second portion of the surface of the component is a serrated region of a gas turbine blade and the first portion of the surface of the component is an underplatform region of a gas turbine blade.

The method of any previous clause, wherein the second portion of the surface of the component comprises an undamaged region of a thermal barrier coating.

The method of any previous clause, wherein the first portion of the surface of the component comprises a damaged region of the thermal barrier coating.

The method of any previous clause, wherein the temperature is from 350 °C to 500 °C.

The method of any previous clause, wherein the pressure is from 0 atmospheric pressure to 1 atmospheric pressure in inert gas.

The method of any previous clause, wherein the treatment temperature is from 600 °C to 1100 °C.

The method of any previous clause, wherein the heating is for a time from 3 to 12 hours.

A coating system on a component, the coating system comprising: a diffusion layer defining a surface, the diffusion layer on a surface of the component; and an outer layer interfaced with the surface of the diffusion layer, the outer layer comprising chromium.

The coating system of any previous clause, wherein the outer layer is substantially free of inclusions.

The coating system of any previous clause, wherein the diffusion layer has a thickness from 1 μm to 10 μm.

The coating system of any previous clause, wherein the outer layer has a porosity from 0% by volume to 5% by volume.

This written description uses examples to disclose the present disclosure, including the best mode, and also to enable any person skilled in the art to practice the disclosure, including making and using any devices or systems and performing any incorporated methods. The patentable scope of the disclosure is defined by the claims, and may include other examples that occur to those skilled in the art. Such other examples are intended to be within the scope of the claims if they include structural elements that do not differ from the literal language of the claims, or if they include equivalent structural elements with insubstantial differences from the literal languages of the claims.

We claim:

1. A method of forming a coating system on a component, the method comprising:
exposing a first portion of a surface of a component to a chromium-containing vapor via physical vapor deposition (PVD) at a temperature and a pressure to form a chromium-containing layer on the first portion of the surface of the component; and
heating the chromium-containing layer at a treatment temperature in a protective atmosphere to form a diffusion layer on the first portion of the surface of the component and an outer layer on the diffusion layer.

2. The method of claim 1, wherein the chromium-containing vapor comprises at least 90 wt. % chromium.

3. The method of claim 1, wherein the chromium-containing vapor is substantially free of a halide.

4. The method of claim 1, wherein the chromium-containing layer has a thickness from 1 μm to 30 μm.

5. The method of claim 1, wherein the outer layer is substantially free of inclusions.

6. The method of claim 1, wherein the outer layer has a porosity from 0% by volume to 5% by volume.

7. The method of claim 1, wherein the diffusion layer has a thickness from 1 μm to 10 μm.

8. The method of claim 1, wherein the component is at least one of a turbine blade, a turbine nozzle, a structural ring, a turbine disk, or a turbine casing.

9. The method of claim 1, further comprising:
prior to exposing the first portion of the surface of the component to the chromium-containing vapor, masking a second portion of the surface of the component.

10. The method of claim 9, wherein the second portion of the surface of the component is a serrated region of a gas turbine blade and the first portion of the surface of the component is an underplatform region of the gas turbine blade.

11. The method of claim 9, wherein the second portion of the surface of the component comprises an undamaged region of a thermal barrier coating.

12. The method of claim 11, wherein the first portion of the surface of the component comprises a damaged region of the thermal barrier coating.

13. The method of claim 1, wherein the temperature is from 350 °C to 500 °C.

14. The method of claim 1, wherein the pressure is from 0 atmospheric pressure to 1 atmospheric pressure in inert gas.

15. The method of claim 1, wherein the treatment temperature is from 600 °C to 1100 °C.

16. The method of claim 1, wherein the heating is for a time from 3 to 12 hours.

17. A coating system on a component, the coating system comprising:
a diffusion layer, the diffusion layer on a surface of a component; and
an outer layer on the diffusion layer, the outer layer comprising chromium.

18. The coating system of claim 17, wherein the outer layer is substantially free of inclusions.

19. The coating system of claim 17, wherein the diffusion layer has a thickness from 1 μm to 10 μm.

20. The coating system of claim 17, wherein the outer layer has a porosity from 0% by volume to 5% by volume.
